(19) United States
(12) Patent Application Publication
(10) Pub. No.: US 2024/0128391 A1
(43) Pub. Date: Apr. 18, 2024

(54) SOLAR BATTERY MODULE AND METHOD FOR MANUFACTURING SAME

(71) Applicant: WASEDA UNIVERSITY, Tokyo (JP)

(72) Inventor: Kohei TATSUMI, Tokyo (JP)

(21) Appl. No.: 18/547,967

(22) PCT Filed: Feb. 28, 2022
(86) PCT No.: PCT/JP2022/008457

§ 371 Date: Aug. 25, 2023

(30) Foreign Application Priority Data
Mar. 1, 2021 (JP) 2021-032159

(51) Int. Cl. H01L 31/05

(52) U.S. Cl. CPC H01L 31/0508; H01L 31/0512

(57) ABSTRACT

Provide is a solar cell module includes: a solar cell; an electrode provided on a surface of the solar cell; a wiring material formed of metal; and plating portions formed of a plating metal between the electrode and the wiring material to join the solar cell and the wiring material. The electrode is a bus bar electrode extending from a first edge of the solar cell to a second edge opposing the first edge, the wiring material is in the form of a strip or wire and is arranged to extend in the direction of the bus bar electrode, and the plating portions are formed at predetermined intervals in the extension direction of the wiring material and locally join the bus bar electrode and the wiring material.

### TECHNICAL FIELD

The technology disclosed in this specification relates to a solar cell module and its manufacturing method.

### BACKGROUND ART

Conventionally, solar cell modules have been known, which electrically connect multiple solar cells using linear wiring materials such as interconnectors. Such solar cell modules typically have a structure in which the wiring materials and the electrodes provided on the solar cells are joined by solder, and soldered joints are formed between the wiring materials and the solar cells (e.g., Patent Document 1).

### CITATION LIST

### Patent Literature

Patent Literature 1: JP 2018-186307 A

### SUMMARY OF THE INVENTION

### Technical Problem

In the solar cell module where the wiring materials are joined to the solar cells as in Patent Document 1, problems such as peeling or breakage of the wiring materials and an increase in resistance are likely to occur, making it difficult to achieve long life. Much of the degradation of such solar cell modules is attributed to the deterioration of the solder caused by corrosion and thermal stress.

The present invention has been made in view of the above points and aims to provide a solar cell module and its manufacturing method capable of achieving long life.

### Solution to Problem

The solar cell module according to the present invention includes multiple solar cells, each having metal electrodes to extract electric power, metal wiring electrically connected to the electrodes of multiple solar cells, plating portions formed from plating metal between the electrodes and the wiring to join the electrodes and the wiring.

The solar cell module according to the present invention is configured with a solar cell having electrodes, metal wiring, and a plating portion formed from plating metal between the solar cell and the wiring to join the solar cell and the wiring.

The manufacturing method of the solar cell module according to the present invention involves a joining step of immersing a plating solution between the joined surface of a strip-formed or wire-shaped wiring metal material and the joined surface of a solar cell electrode, causing columnar crystals of plated metal grown from each of the joined surfaces to meet each other, thereby joining the wiring material and the electrode with the plated metal.

### Advantageous Effects of the Invention

According to the present invention, since the wiring and the electrode of the solar cell are joined using the plating portions formed from plating metal, detachment of the wiring from the electrode and other issues are prevented or suppressed. Moreover, the stress applied to the plating metal of the joint is effectively relieved, enhancing the durability of the junction between the wiring and the solar cell, thereby achieving longer life of the solar cell module.

### BRIEF DESCRIPTION OF DRAWINGS

FIG. 1 is a side view of the solar cell module according to the first embodiment.

FIG. 2 is a top view of the solar cell connected to the interconnector.

FIG. 3 is a sectional view taken along the III-III line in FIG. 2 and enlarged to show the plating portion.

FIG. 4 is a side view of the solar cell module according to the second embodiment.

FIG. 5 is a perspective view showing the finger electrode and bus bar electrode formed on the surface of the solar cell and the interconnector joined to the bus bar electrode.

FIG. 6 is a cross-sectional view showing the state where the wire-shaped interconnector is joined to the bus bar electrode.

FIG. 7 is a side view of the solar cell module showing an example where a pair of connected connector parts are used as the interconnector.

FIG. 8 is a cross-sectional view showing an example where the finger electrode, bus bar electrode, and interconnector have a plating metal coating layer formed on their surfaces.

FIG. 9 is a SEM image of a cross-section of the plating portion.

FIG. 10 is an EBSD image measuring the crystal orientation of the cross-section of the plating portion.

FIG. 11 is a graph showing the difference in characteristic loss due to plating and soldering joints in a temperature cycle test of the solar cell module.

FIG. 12 is a graph showing the Vickers hardness ratio before and after heat treatment of the plating portion at each heat treatment temperature.

FIG. 13 is a graph showing the ratio of characteristic degradation of the solar cell module after a thermal stress test of the plating portion with and without heat treatment, at each heat treatment temperature.

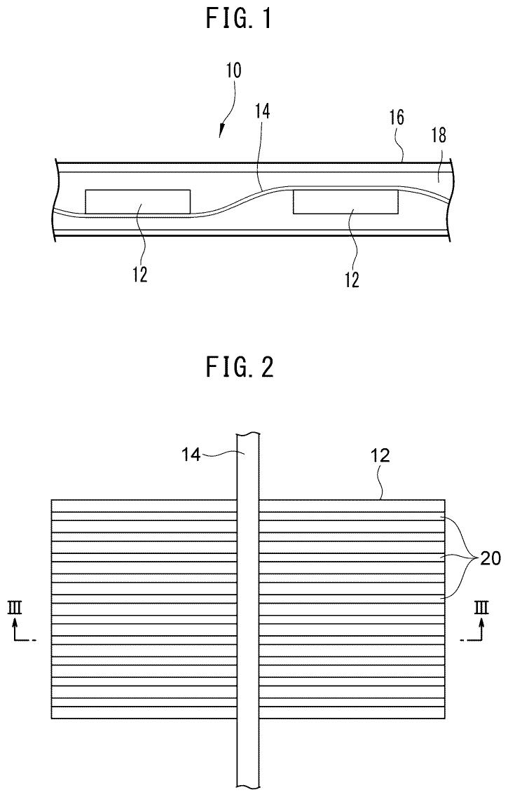

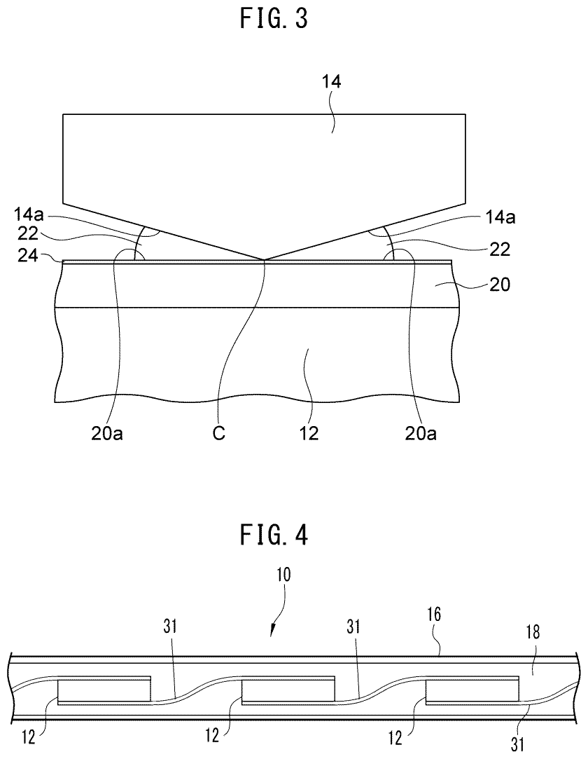

### DESCRIPTION OF EMBODIMENTS

[First Embodiment] In this embodiment, the solar cell module is composed of a plurality of solar cells electrically connected by wiring and interconnectors. As shown in FIG. 1, the solar cell module 10 includes a plurality of solar cells 12 and interconnectors 14 as wiring materials for electrically connecting these solar cells 12. In the solar cell module 10, each solar cell 12 and interconnector 14 are housed in the housing 16 and sealed with sealing material 18. In this embodiment, as will be described in detail later, the interconnector 14 is in a strip form and arranged linearly, and is joined to a plurality of electrodes 20 (see FIG. 2) for extracting power provided on the solar cells 12 through plating portions 22 (see FIG. 3). Thus, the interconnector 14 and the plurality of electrodes 20 are electrically connected. In this example of the embodiment, the plurality of solar cells 12 are arranged linearly at predetermined intervals. However, the arrangement of the plurality of solar cells 12 is not limited thereto and may be arranged in a matrix, for example.

Each solar cell 12 is mainly formed of silicon (Si) and has a flat plate shape. The interconnector 14 is formed of copper and is elongated in a strip form. By electrically connecting the front-side electrode 20 of one of the adjacent solar cells 12 and the rear-side electrode 20 of the other solar cell 12 using the interconnector 14, multiple solar cells 12 are connected in series. Although not shown in the drawings, electrodes are provided on the surfaces opposite to the surfaces where the interconnectors 14 are connected on each solar cell 12, and they are electrically connected by another interconnector (not shown).

As shown in FIG. 2, each solar cell 12 has multiple electrodes 20 formed on both the front and rear surfaces. The multiple electrodes 20 extend linearly in a direction orthogonal to the extension direction (direction of extension) of the interconnector 14 and are arranged at predetermined intervals in the extension direction of the interconnector 14. The interconnector 14 is locally joined to the solar cell 12, meaning that not all of the surfaces facing the solar cell 12 are joined but only the parts that intersect with the electrodes 20 are joined. In this example, the electrodes 20 are illustrated as finger electrodes, but the electrodes may be other types, such as bus bar electrodes, without limitation. In FIGS. 2, 6, and 8, the hatching showing the cross-section is omitted.

Due to the localized joining of the interconnector 14, the stress applied to the plating portion 22 is effectively relieved compared to the configuration where all the surfaces facing the solar cell 12 are joined. As a result, the durability of the plating portion 22 is increased, and the solar cell module 10 is provided with longer life compared to conventional solar cell modules.

As shown in FIG. 3, the interconnector 14 has a mountain-shaped cross-section that protrudes on the side in contact with the electrode 20 of the solar cell 12, and its top is joined in contact with the electrode 20. The top of the interconnector 14 extends linearly in the extension direction of the interconnector 14, so the interconnector 14 and the electrode 20 are in linear contact. It should be noted that as long as the top part of the interconnector 14 is in proximity to the electrode 20 within a certain range in the extension direction of the interconnector 14, even if the top part of the interconnector 14 partially or completely moves away from the electrode 20, it is still considered to be in close proximity. Moreover, although the embodiment exemplifies the interconnector 14 with a mountain-shaped cross-section, the shape of the interconnector is not limited to this. For example, the interconnector may be wire-shaped with a circular cross-section. In this case, the outer circumferential surface of the interconnector is joined in contact or in close proximity to the electrode.

The interconnector 14 has a part of its surface as a joined surface 14a to be joined with the electrode 20 of the solar cell 12. The electrode 20 has silver paste 24 sintered on its surface, and a part of its surface serves as a joined surface 20a to be joined with the interconnector 14. In other words, the electrode 20 is substantially formed of silver (sintered silver). The distance between the joined surface 14a of the interconnector 14 and the joined surface 20a of the electrode 20 gradually increases from the contact portion C between the interconnector 14 and the electrode 20 towards the outer side. In other words, as the portions of the joined surfaces 14a, 20a move away from the contact portion C where these surfaces 14a, 20a are in contact with each other, their spacing continuously increases. It should be noted that even if the cross-section of the interconnector, as mentioned above, is circular and its outer circumferential surface is in contact with the electrode in a linear fashion, the spacing between the two joined surfaces increases as the contact portion moves away.

The plating portion 22 is formed between the interconnector 14 and the solar cell 12 by plating using a plating solution, and the plating portion 22 is formed as nickel (Ni) as a metal. The plating portion 22 is formed in a state where void generation is prevented or suppressed between the joined surface 14a of the interconnector 14 and the joined surface 20a of the electrode 20 by using a plating solution. As a result, the occurrence of interfacial breakage is prevented or suppressed.

In this embodiment, although the example of the interconnector 14 and the electrode 20 of the solar cell 12 being in linear contact is shown, it is also possible for the interconnector 14 to have pointed parts in some areas and be joined with the electrode 20 of the solar cell 12 in such a way that the pointed parts are joined. In this case, the interconnector 14 and the electrode 20 may be in point contact. Alternatively, the interconnector 14 and the electrode 20 may be in point or linear proximity. In other words, the joined surfaces 14a, 20a of the interconnector 14 and the electrode 20 may have their spacing gradually increase as parts of these joined surfaces 14a, 20a move away from each other. Furthermore, even if the interconnector 14 and the electrode 20 are in point or linear proximity, it means that the parts of the joined surfaces 14a, 20a are in a state of being in point or linear contact and that the spacing between these parts of the joined surfaces is small. In such a case, it is preferable to have parts where the spacing between the joined surfaces 14a, 20a increases as they move away from the contact portion C or the closely adjacent part.

As described above, the configuration where the spacing between the joined surfaces 14a, 20a is widened from the contact portion C or the closely adjacent part outward results in preventing or suppressing the generation of voids when columnar crystals that grow from each joined surface 14a, 20a form the plating portion 22. As a result, the bonding strength between the interconnector 14 and the electrode 20 of the solar cell 12 can be enhanced. Additionally, the growth of columnar crystals forming the plating portion 22 from the joined surface 20a of the electrode 20, where silver paste 24 is sintered on the surface, can prevent corrosion of the silver paste 24 and, consequently, inhibit the decrease in the lifespan of the solar cell module 10 associated with silver corrosion.

Furthermore, even if some parts of the interconnector 14 and the electrode 20 of the solar cell 12 are in planar contact or proximity, it is preferable to have parts where the spacing between the joined surfaces 14a, 20a of the interconnector 14 and the electrode 20 increases as they move away from the contact portion C or the closely adjacent part. In such a configuration, the generation of voids can also be prevented or suppressed when columnar crystals that grow from each joined surface 14a, 20a form the plating portion 22.

As mentioned above, by bonding the interconnector 14 and the solar cell 12 using the plating portion 22, a good and strong bond is achieved between the interconnector 14 and the solar cell 12. In the solar cell module 10, the bonding between the interconnector 14 and the solar cell 12 is replaced from the conventional solder bonding used for bonding between wiring material and solar cells in conventional solar cell modules to bonding using the plating metal of nickel in the plating portion 22. This change effectively prevents or suppresses corrosion and stress deformation of the interconnector 14 and the solar cell 12, resulting in a good bond. Particularly, the use of nickel for the plating portion 22 has the advantage that the difference in thermal expansion coefficient between nickel and the material of the interconnector 14, copper, is smaller than the difference between solder and copper. Therefore, delamination of the interconnector 14 due to degradation of the plating portion 22 caused by repetitive temperature changes is less likely to occur. This ensures a good bond between the interconnector 14 and the solar cell 12, reducing resistance increase associated with bonding degradation, and consequently suppressing a decrease in power generation efficiency.

During the manufacturing process of the solar cell module 10 where the interconnector 14 and the solar cell 12 are bonded, it is preferable to perform heat treatment either without performing it or for the purpose of relieving (removing or reducing) the strain in the plating portion 22. By removing or relaxing the strain in the plating portion 22 through heat treatment, flexibility can be provided to the plating portion 22, i.e., the bond between the interconnector 14 and the electrode 20. This can suppress the destruction of the plating portion 22 due to expansion and contraction caused by temperature changes during usage, thereby improving the lifespan of the solar cell module 10. In this embodiment, the heat treatment is performed to relieve the distortion of the plating portion 22, achieving an extended lifespan of the solar cell module 10.

In the manufacturing process of the solar cell module 10, heat treatment is performed to allow diffusion of the plating metal, which constitutes the silver as the undercoat electrode on the surface of the electrode 20, and the plating portion 22. This enhances adhesion and peel resistance. However, if the heat treatment temperature is too high, it may lead to an increase in electrical resistance, so it is preferable to perform heat treatment at a low temperature. Specifically, when the plating metal is nickel, heat treatment is preferably conducted at 500° C. or below, and when the plating metal is copper, it is preferable to conduct heat treatment at 450° C. or below. The thickness of the diffusion layer formed by the diffusion of the metal constituting the undercoat electrode and the plating metal is preferably 0.005 μm or more and 1 μm or less.

The relaxation or removal of the strain in the plating portion 22 can be confirmed as a decrease in Vickers hardness. After the aforementioned heat treatment, the Vickers hardness of the plating portion 22, when the plating metal is nickel, is preferably within the range of 100 to 250 HV, and more preferably within the range of 100 to 230 HV. In other words, when conducting the heat treatment, it is preferable to perform it in a way that the Vickers hardness of the plating portion 22 made of nickel falls within the range of 100 to 250 HV or more preferably within the range of 100 to 230 HV. The Vickers hardness of the plating portion 22 can be measured using a well-known measurement method in accordance with the Japanese Industrial Standard JIS Z 2244 using a micro Vickers hardness tester.

In the solar cell module 10, while nickel is used for the plating metal constituting the plating portion 22, it is not limited to nickel. The plating metal constituting the plating portion 22 may be other than nickel, such as nickel alloys, copper, and copper alloys. Nickel alloys include Ni—P, Ni—B, Ni—S, etc., and copper alloys include Cu—Zn, Cu—Sn, Cu—Ag, Cu—Pd, etc. To suppress an increase in electrical resistance, it is preferable for the nickel alloy to contain only a trace amount (e.g., 10% or less) of elements other than nickel, and for the copper alloy to contain only a trace amount (e.g., 10% or less) of elements other than copper. From the perspective of reducing the difference in thermal expansion coefficient with silicon, which constitutes the solar cell 12, it is also preferable for the plating metal constituting the plating portion 22 to be an Fe—Ni alloy having a nickel content in the range of 32% to 45%. Such an Fe—Ni alloy-formed plating portion 22 is particularly useful when the solar cell module 10 is used in environments with large temperature fluctuations resulting in large thermal stress.

Next, the manufacturing method of the solar cell module 10 according to this embodiment will be described. In this embodiment, the joining method between the interconnector 14 and the solar cell 12 is particularly explained. As for the manufacturing processes other than the joining process between the interconnector 14 and the solar cell 12 in the manufacturing process of the solar cell module 10, known manufacturing methods for solar cell modules can be used, so their explanation is omitted.

First, prepare the interconnector 14. For example, process the part of the band-shaped material formed of copper, which will be joined to the electrode 20 of the solar cell 12, into a mountain shape (tapered shape) to create the interconnector 14. Next, perform alkaline degreasing and acid cleaning on the surfaces of the interconnector 14 and the electrode 20 to remove dust, oil, etc. Then, in the coating step, apply an organic film such as a resist film to the parts of the surfaces of the interconnector 14 and the electrode 20 where plating treatment is unnecessary (excluding the joined surfaces 14a, 20a). This way, selective plating treatment is performed only on the parts of the interconnector 14's surface that intersect with the electrode 20 on the solar cell 12. Note that, when performing plating treatment with electrolytic plating, if there is a sufficiently insulating film on the parts of the solar cell 12's surface where plating treatment is unnecessary, the resist film in that part can be omitted. Additionally, if using a wire-shaped interconnector, a drawn one can be used.

Next, in the joining step, perform plating treatment to join the joined surfaces 14a of the interconnector 14 and the joined surfaces 20a of the electrode 20 of the solar cell 12. The plating treatment is conducted by fixing the tips of the parts of the interconnector 14 processed into a mountain shape in a state of linear contact or proximity to each electrode 20 of the solar cell 12. If using a wire-shaped interconnector, the outer peripheral surface of the wire is fixed in a state of linear contact or proximity to each electrode 20.

In the plating treatment, for example, a sulfamate bath can be used. This allows the plating solution to permeate between the joined surfaces 14a of the interconnector 14 and the joined surfaces 20a (silver paste 24) of the electrode 20 of the solar cell 12 to form the plating portion 22. In this plating treatment, the temperature of the plating solution is preferably about 55° C. Also, when performing plating treatment using an electrolytic plating, it is preferable to electrically connect the interconnector 14 and each electrode 20 of the solar cell 12 and keep them at the same potential, particularly the joined surfaces 14a, 20a, at the same potential. Furthermore, it is preferable to use a plating solution adjusted so that columnar crystals meet from the small spacing region between the joined surfaces 14a and 20a toward the outside in sequential order.

By performing the plating treatment as described above on the interconnector 14 and each electrode 20 of the solar cell 12, elongated nickel columnar crystals grow from the surfaces of the interconnector 14 and the electrodes 20 of the solar cell 12, respectively. The columnar crystals grown from the joined surface 14a of the interconnector 14 and the joined surface 20a of each electrode 20 of the solar cell 12 collide and meet at substantially equidistant portions to form a joining interface. This joining interface is formed from regions where the spacing between the joined surfaces 14a and 20a is narrow to wider regions. As a result, the occurrence of voids in the plating portion 22 is prevented or suppressed.

Additionally, by selectively performing the plating treatment only on the parts of the interconnector 14's surface that intersect with the electrode 20 on the solar cell 12, the interconnector 14 is only joined to the electrode 20 through the plating portion 22. Consequently, compared to a configuration where the entire area of the side of the interconnector 14 facing the solar cell 12 is joined, stress applied to the plating portion 22 is effectively relieved, thereby enhancing the durability of the plating portion 22.

Next, in the heat treatment step, a heat treatment is performed by heating the interconnector 14 and the solar cell 12 that are joined by the plating portion 22. For example, in the case where the plating metal is nickel, the heat treatment is preferably conducted in the range of 200° C. to 500° C. in an atmosphere. This is because heat treatment at 200° C. or above reduces the internal stress of the electrolytic nickel plating and increases thermal stress resistance. Also, by keeping the heat treatment temperature below 500° C., it minimizes adverse effects on the characteristics of the solar cell 12 primarily formed of silicon, such as an increase in electrical resistance and coarsening of metal crystals caused by diffusion. By performing the heat treatment, the strain in the plating portion 22 is reduced compared to before the heat treatment. Specifically, when the plating metal is nickel, the Vickers hardness of the plating portion 22 decreases from about 275 HV before the heat treatment to about 140 HV after the heat treatment. For example, in the case where the plating metal is copper, which has a lower melting point than nickel, it is preferable to perform the heat treatment in the temperature range of 150° C. to 450° C.

Through the above steps, the interconnector 14 and each electrode 20 of the solar cell 12 are joined. The joining according to the above steps can be performed collectively for multiple solar cells 12. The multiple solar cells 12 with the interconnector 14 joined are then housed in the housing 16 and sealed with the sealing material 18 to become the solar cell module 10. The manufactured solar cell module 10 has enhanced durability of the plating portion 22, resulting in increased lifespan.

### Second Embodiment

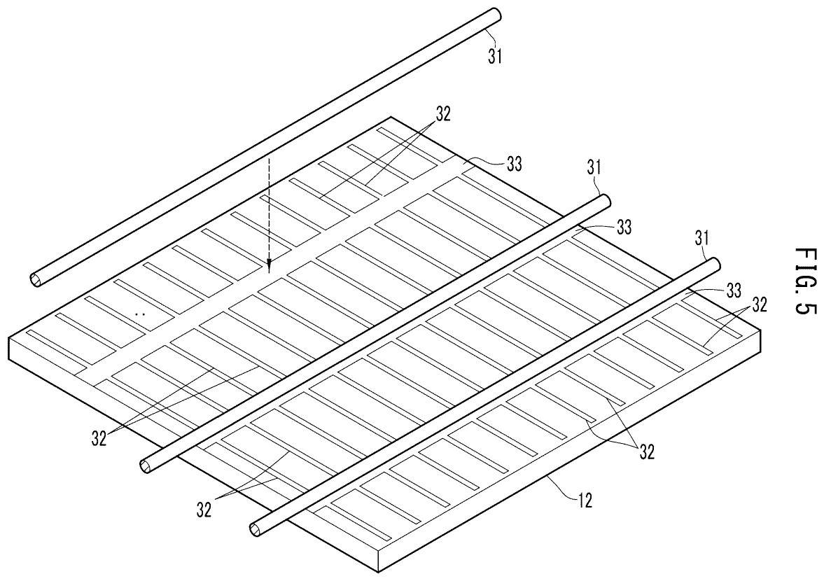

FIG. 4 shows a solar cell module 10 according to a second embodiment. The following explanation is the same as the first embodiment, and the same components are indicated by the same reference numerals, and their detailed descriptions are omitted.

In the solar cell module 10 shown in FIG. 4, one interconnector 31 connects two adjacent solar cells 12, and multiple solar cells 12 are electrically connected in series by multiple interconnectors 31. In this example of the solar cell module 10, multiple solar cells 12 are arranged in a matrix, and two adjacent solar cells 12 in each column are connected by one interconnector 31. That is, one interconnector 31 connects the surface electrode of one solar cell 12 and the back surface electrode of the other solar cell 12. When focusing on one solar cell 12, the surface electrode of the solar cell 12 is connected to the back surface electrode of the adjacent solar cell 12 on the left side through the interconnector 31, and the back surface electrode of the solar cell 12 is connected to the surface electrode of the adjacent solar cell 12 on the right side through another interconnector 31.

Each solar cell 12 has different electrodes on its front and back surfaces, for example, the front surface electrode is the positive pole, and the back surface electrode is the negative pole. As a result, each row of solar cells 12 is electrically connected in series through multiple interconnectors 31. The arrangement of multiple solar cells 12 and the manner of connecting interconnectors 31 are not limited to specific configurations.

In FIG. 5, multiple finger electrodes 32 are provided on the surface of the solar cell 12. The finger electrodes 32 extend in one direction as linear strips and are formed parallel to each other at regular intervals. Additionally, bus bar electrodes 33 are provided on the surface of the solar cell 12 to collect the current flowing through the finger electrodes 32 generated by the solar cell 12. In this example, three bus bar electrodes 33 are provided at predetermined intervals and are arranged perpendicular to the finger electrodes 32. They are electrically connected at positions where they intersect with multiple finger electrodes 32. Both the finger electrodes 32 and bus bar electrodes 33 are formed using silver (Ag), and the surface of the bus bar electrode 33 becomes one of the joined surfaces. It is also possible to form the finger electrodes 32 and bus bar electrodes 33 using materials such as copper or nickel.

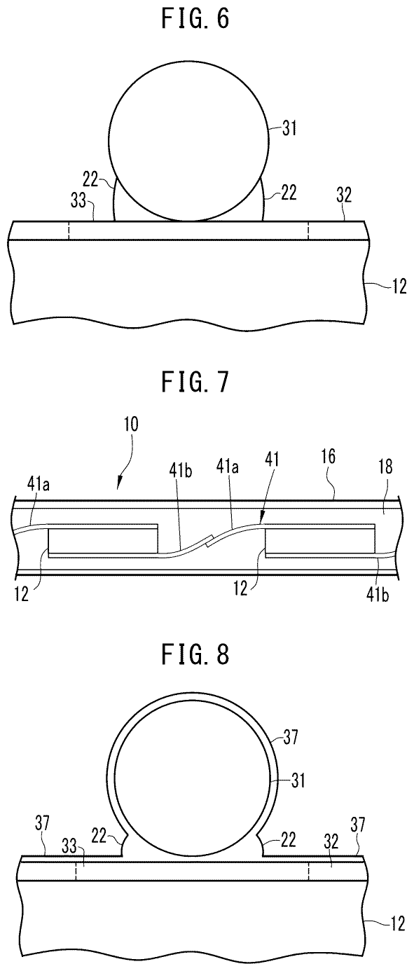

Three interconnectors 31 corresponding to the three bus bar electrodes 33 are provided, and each interconnector 31 is arranged to extend in the direction perpendicular to the finger electrodes 32, i.e., in the direction of the bus bar electrode 33. Each interconnector 31 is bonded to its corresponding bus bar electrode 33 using plating portions 22 (refer to FIG. 6). In this example, the interconnector 31 is wire-shaped with a circular cross-section made of highly conductive metal, such as copper wire. It is also possible to use interconnectors with a shape like a mountain (among other shapes) as in the first embodiment.

As shown in FIG. 6, the interconnector 31 is bonded to the bus bar electrode 33 by the plating portions 22, with the outer surface of the interconnector 31 in contact with the bus bar electrode 33 and bonded to them in a linear contact arrangement. In this example, multiple plating portions 22 are discontinuously formed in the extension direction of the interconnectors 31. In other words, the plating portions 22 are formed at specific intervals along the extension direction of the interconnector 31, and the interconnector 31 is electrically connected to the bus bar electrode 33 at multiple localized points. This configuration allows relieving the stress acting on the plating portions 22 due to the difference in thermal expansion coefficients between the interconnectors 31 and the solar cell 12. As a result, the durability of the plating portions 22 is improved, leading to a longer lifespan of the solar cell module 10 as compared to conventional solar cell modules. On the back surface of the solar cell 12, finger electrodes and bus bar electrodes are also provided, and the interconnector 31 is bonded to the bus bar electrode 33 using plating portions.

Furthermore, it is possible to bond the interconnector 31 and the bus bar electrode 33 in close proximity using plating portions 22. The interconnectors 31 may also be positioned away from the bus bar electrode 33 in parts where they are not bonded. Alternatively, the plating portions 22 can be continuously formed in the extension direction of the interconnector 31. In this case, the entire area of the interconnector 31 on the bus bar electrode 33 may be bonded to the bus bar electrode 33 using the plating portion 22. Even in such continuous and long bonding with the plating portion 22, the structure of the plating portion 22 is similar to that in the case of localized bonding. Therefore, even in this bonding configuration, the plating portions 22 provide reliable bonding, preventing or suppressing interface breakage, corrosion, or stress deformation between the interconnector 31 and the solar cell 12, thus achieving a longer lifespan for the solar cell module 10.

In the above example, the interconnector 31 is formed as a single unit during its manufacturing stage. However, as shown in FIG. 7, it is also possible to join a pair of connector parts 41a and 41b, which are joined to adjacent solar cells 12, to form a single interconnector 41. In this example, one end of connector part 41a is joined to the bus bar electrode 33 on the surface of the solar cell 12 using the plating portion 22. Similarly, one end of connector part 41b is joined to the bus bar electrode on the back surface of the solar cell 12 using the plating portion 22. Connector parts 41a and 41b are circular copper wires in this example, but they could also be shaped as bands with a mountain-shaped cross-section, among others. The other end of connector parts 41a and 41b may have shapes that facilitate their joining.

The connector part 41a joined to the surface of the solar cell 12 and the connector part 41b joined to the back surface are joined to the solar cell 12 so that they protrude in opposite directions from the solar cell 12 towards each other. In the illustrated example, connector part 41a protrudes to the left side of the solar cell 12, and connector part 41b protrudes to the right side of the solar cell 12, where their other ends are joined together to electrically connect them. This connection can be achieved using methods such as ultrasonic bonding or spot welding.

With the above-described interconnector 41, there is no need to join multiple interconnectors individually or continuously for multiple solar cells 12. Instead, interconnectors 41 can be joined efficiently and compactly to multiple solar cells 12 using a suitable processing device. Furthermore, since connector parts 41a and 41b are joined together with the same material, there are no issues related to thermal expansion differences, and the joining process is simplified.

As shown in FIG. 8, it is also possible to cover the surface of the bus bar electrode 33 and the outer surface of the interconnector 31, where no plating portions 22 are formed, as well as the surface of the finger electrode 32, with a plating metal. In this example, a coating layer 37 made of a plating metal is formed on the surface of the bus bar electrode 33 and the outer surface of the interconnector 31, where no plating portions 22 are formed, and on the surface of the finger electrode 32. The coating layer 37 can be formed by conducting plating without applying a resist film to the part to be formed. By creating the coating layer 37, protection against corrosion and oxidation, etc., is provided for the surface of the finger electrode 32, the surface of the bus bar electrode 33, and the outer surface of the interconnector 31.

In the above-described embodiments, the interconnector is joined to the electrodes (finger electrode, bus bar electrode) formed on the surface of the solar cell. Alternatively, the interconnector can be joined to a plating portion formed between the joined surface of the interconnector and a part of the silicon substrate surface that constitutes the solar cell, thereby improving the bonding strength between the interconnector and the solar cell. In this case, the surface of the silicon substrate, the bus bar electrode, and the finger electrode, which serves as the joined surface of the solar cell (silicon substrate), may be formed with plating metals using the plating process during the joining of the interconnector. The surface of the silicon substrate serving as the joined surface, the bus bar electrode, and the finger electrode can undergo treatment to remove the insulating layer on the surface, such as by etching, or form an underlying conductive film for better conductivity.

### Example 1

(1) Sample Preparation: In the first example, a sample of an interconnector formed as a copper wire and a single solar cell joined by a plating portion was prepared to observe the joint section. The interconnector used was a copper wire with a diameter of 300 μm made of copper (99.9% purity). The solar cell was a rectangular prism with dimensions of 52×26 mm for the long and short sides and a thickness of 0.17 mm. Nickel was used as the plating metal for the plating portion. The sample preparation method was the same as the manufacturing method described in the previous embodiment.

First, the surfaces of the interconnector and the bus bar electrode were subjected to alkali degreasing and acid cleaning to remove dust and oil. Subsequently, a resist film was applied to the parts of the surface of the interconnector and the solar cell where plating treatment was not required.

After applying the resist film, the interconnector's outer surface was fixed in contact with the solar cell's electrode in a linear manner, and plating treatment was performed to form a plating portion between the joined surface of the interconnector and the joined surface of the solar cell. In the plating process, a sulfamate bath was used, and the temperature of the plating solution was set to 55° C., with a plating current density of 1.5 A/dm2. In this first example, the interconnector was continuously joined to the electrode at a specific length, and the plating width was set to 0.14 mm. Following these steps, a sample of the joint structure was prepared.

(2) Observation of Crystal at the Joint Section:

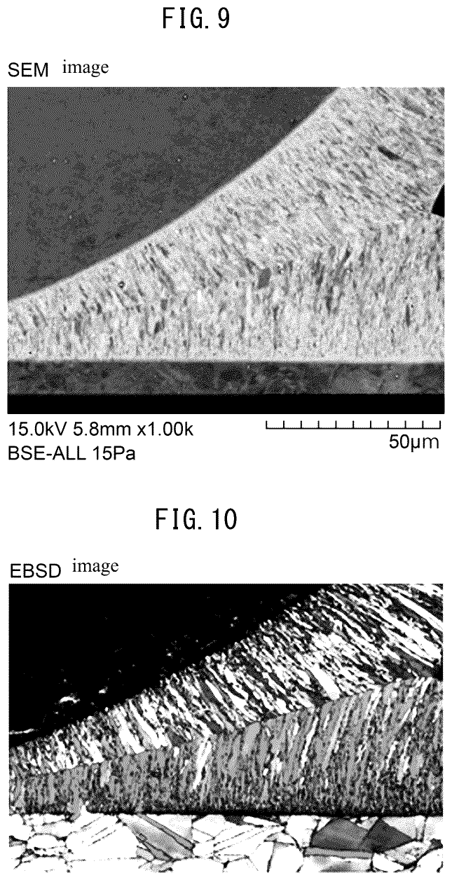

The prepared samples were observed using a scanning electron microscope (SEM) to examine the cross-section of the plating portion (joint section). Electron backscatter diffraction (EBSD) was used to measure the crystal orientation. SEM images and EBSD images are shown in FIGS. 9 and 10, respectively. From these observations, it was confirmed that crystals grown from the joined surface of the interconnector and crystals grown from the joined surface of the solar cell's electrode both have columnar shapes, and they share a crystal orientation of <001> in the growth direction. Moreover, no voids or defects were observed in the meeting interface that appeared in the vicinity of the joined surface of the interconnector and the electrode of the solar cell, indicating a strong joint. In this case, the meeting of columnar crystals forms the meeting interface, and there are no voids or interface fractures.

### Example 2

In the second example, samples were prepared by joining an interconnector made of copper (99.9% purity) with a diameter of 300 μm and multiple solar cells using a plating portion. Afterward, the samples were subjected to temperature cycle tests (TC test), and the electrical performance losses were evaluated after the test. The interconnector and solar cells used were the same as those in the first example, and the joint between the interconnector and the solar cell's electrode was carried out using the same method as in the first example. Nickel was used as the plating metal for the plating portion. As a comparison, samples were prepared by joining the interconnector and the electrodes of the solar cells using solder instead of plating.

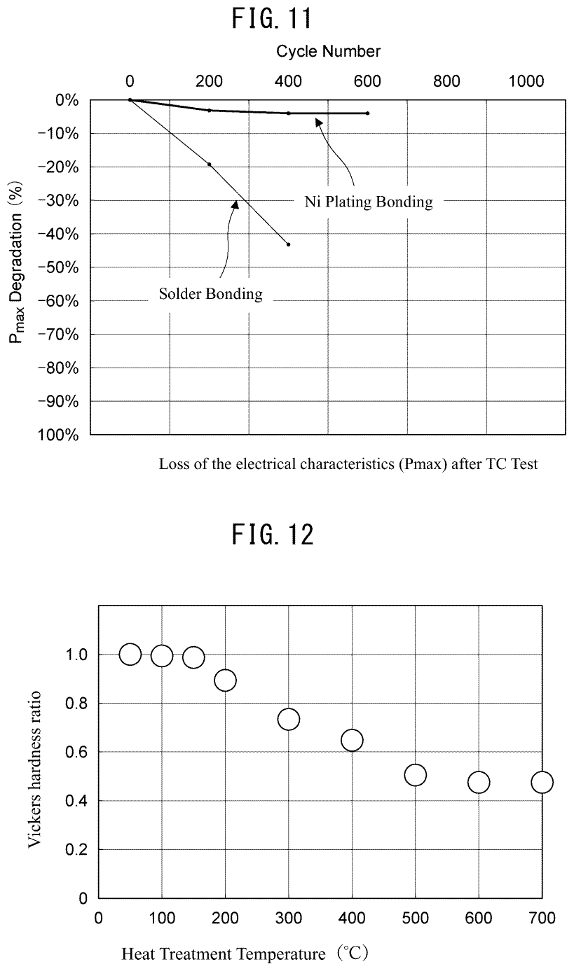

The prepared samples and the comparison samples were subjected to temperature cycle tests. The temperature cycle tests were conducted using an Espec temperature cycle test machine, with the test conditions set at −40° C. to 150° C. for the samples of the second example and −40° C. to 85° C. for the comparison samples, both for 600 cycles. The electrical performance loss (decrease in maximum output (Pmax)) was evaluated after 200 cycles, 400 cycles, and 600 cycles for each sample. The electrical properties were measured using a tabletop solar simulator with a Xenon lamp, which irradiated light with an intensity of 100 mW/cm2, and IV measurements were performed. The Fill Factor (Pm (=Vm×Im) divided by Vo×Is) was measured by IV measurement, and the percentage of its reduction was calculated. The results are shown in FIG. 11.

As shown in FIG. 11, the comparison samples joined using solder showed a significant decrease in electrical performance as the number of temperature cycles increased. On the other hand, for the samples joined using plating, there was hardly any reduction in electrical performance, even with an increase in the number of temperature cycles. From these results, it was confirmed that the solar cell module joined using plating with nickel as the plating metal exhibited significantly improved degradation of electrical performance under high-temperature conditions compared to the conventional soldered solar cell module.

### Example 3

In the third example, samples were prepared by joining an interconnector made of copper (99.9% purity) with a diameter of 200 μm and multiple solar cells using a plating portion. After the samples were prepared, they were subjected to heat treatment in the atmosphere for 30 minutes, and the Vickers hardness ratio of the plating portion before and after heat treatment was evaluated at various heat treatment temperatures. The electrical performance degradation ratio of the samples after temperature cycle testing with and without heat treatment was also evaluated at different heat treatment temperatures. The plating metal used for the plating portion was nickel, and the joint between the interconnector and the solar cell's electrode was performed using the same method as in the second example. Vickers hardness measurements were performed using a Matsuzawa Precision MHT-1 micro-Vickers testing machine, following the standard measuring method according to Japanese Industrial Standard JIS Z 2244. The temperature cycle tests were conducted using an Espec temperature cycle test machine for 500 cycles.

As shown in FIG. 12, the evaluation of Vickers hardness showed a decrease in hardness of the plating portion at heat treatment temperatures of 200° C. or higher. The Vickers hardness ratio was approximately 0.5 at around 500° C., and increasing the heat treatment temperature did not lead to a significant further reduction in hardness. The Vickers hardness before heat treatment was approximately 275HV, which decreased to approximately 140HV after heat treatment at 500° C.

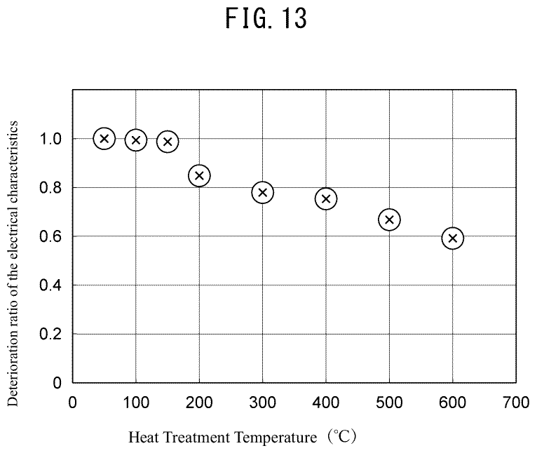

In this embodiment, the deterioration ratio of the electrical characteristics after temperature cycling test for the samples that did not undergo heat treatment was set as 100%, and the deterioration of electrical characteristics was evaluated in comparison to this reference. As shown in FIG. 13, the evaluation of electrical characteristic deterioration after the temperature cycling test revealed that the deterioration ratio of electrical characteristics was approximately 0.8 at heat treatment temperatures of 200° C. or higher, indicating a decrease in the deterioration rate of electrical characteristics. Thus, it was found that at heat treatment temperatures of 200° C. or higher, the electrical characteristics are less likely to deteriorate. Moreover, as the heat treatment temperature increased, a further decrease in the deterioration rate of electrical characteristics was observed, and in the case of samples subjected to 600° C. heat treatment, the deterioration ratio of electrical characteristics decreased to approximately 0.6. Based on these results, it is preferable to keep the heat treatment temperature within the range of 200° C. to 500° C., which minimizes the potential adverse effects on the characteristics of the solar cell below 500° C. Conducting the heat treatment within this temperature range improves the adhesion between the interconnector and the electrode and facilitates stress relaxation of the plating metal.

### REFERENCE SIGNS LIST

10: Solar Cell Module
12: Solar Cell
14, 31, 41: Interconnector (Wiring Material)
14a, 20a: Joined Surface
20: Electrode
22: Plating Portion
32: Finger Electrode
33: Bus bar Electrode
41a, 41b: Connector Parts

1. (canceled)

2. (canceled)

3. A solar cell module comprising:
a solar cell,
an electrode provided on a surface of the solar cell,
a wiring material formed of metal, and
plating portions formed of a plating metal between the electrode and the wiring material to join the solar cell and the wiring material,
wherein the electrode is a bus bar electrode extending from a first edge of the solar cell to a second edge opposing the first edge, the wiring material is in the form of a strip or wire and is arranged to extend in the direction of the bus bar electrode, and the plating portions are formed at predetermined intervals in the extension direction of the wiring material and locally join the bus bar electrode and the wiring material.

4. The solar cell module according to claim 3, wherein the plating metal is nickel or a nickel alloy, and Vickers hardness of the plating portion is within the range of 100 to 250 HV.

5. The solar cell module according to claim 3, wherein the plating metal is copper or a copper alloy, and Vickers hardness of the plating portion is within the range of 40 to 105 HV.

6. The solar cell module according to claim 3, wherein the electrode is made of silver.

7. The solar cell module according to claim 3, wherein the wiring material is made of copper.

8. The solar cell module according to claim 3, wherein the plating portion is composed of columnar crystals extending from the electrode's joined surface toward the wiring material's joined surface and from the wiring material's joined surface toward the electrode's joined surface.

9. The solar cell module according to claim 3, wherein the joined surface of the wiring and the electrode makes contact in a point-like or line-like manner, or is in close proximity in a point-like or line-like manner.

10. (canceled)

11. The solar cell module according to claim 3,
wherein the solar cell includes a plurality of finger electrodes provided parallel to each other and crossing the bus bar electrode.

12. The solar cell module according to claim 3, wherein the electrode is formed of a plating metal selected from copper, silver, and nickel.

13. The solar cell module according to claim 3, further comprising other solar cell adjacent to the solar cell, wherein the wiring material of the solar cell and the wiring material of the other solar cell are joined together by a pair of connector parts in the form of a strip or wire.

14. A method for manufacturing the solar cell module according to claim 3, comprising:
the steps of applying a resist film to portions of the surfaces of the wiring material and the electrode where plating treatment is unnecessary,
immersing the wiring material's joined surface and the electrode's joined surface in a plating solution to bring columnar crystals of plating metal grown from each joined surface into contact with each other, and thereby joining the wiring material and the electrode with the plating metal.

15. (canceled)

16. The method for manufacturing a solar cell module according to claim 14, wherein in the joining step, the wiring material of copper and the plating metal of nickel are used.

17. The method for manufacturing a solar cell module according to claim 14, further performing a heat treatment step on the plated metal after the joining step, wherein the heat treatment heats the plated metal to a temperature in the range of 200° C. to 500° C.

18. (canceled)

19. (canceled)

20. The solar cell module according to claim 3, further comprising other solar cell adjacent to the solar cell, wherein the wiring material is connected to the electrode of the solar cell and the electrode of the other solar cell.
